(19) United States
(12) Patent Application Publication
(10) Pub. No.: US 2025/0226362 A1
(43) Pub. Date: Jul. 10, 2025

(54) LIGHT EMITTING DIODE PACKAGE WITH IMPROVED LIGHT QUALITY

(71) Applicant: LUMILEDS LLC, San Jose, CA (US)

(72) Inventor: Cheng Wei HUNG, Taipei City (TW)

(73) Assignee: LUMILEDS LLC, San Jose, CA (US)

(21) Appl. No.: 18/421,011

(22) Filed: Jan. 24, 2024

(30) Foreign Application Priority Data
Jan. 9, 2024 (WO) PCT/CN2024/071294

(51) Int. Cl. H01L 25/075; H01L 23/00; H01L 33/50; H01L 33/56; H01L 33/60; H01L 33/62

(52) U.S. Cl. CPC H01L 25/0753; H01L 24/48; H10H 20/856; H01L 2224/48137; H01L 2224/48245; H01L 2924/12041; H10H 20/8515; H10H 20/854; H10H 20/857

(57) ABSTRACT

A light emitting diode package is provided. The light emitting diode package includes molded lead frame package. The molded lead frame package includes a lead frame that defines a cavity. The light emitting diode package includes a reflector on the molded lead frame package in a center of a cavity. The light emitting diode package includes chips mounted on the molded lead frame package. The chips are in a symmetric shape around the reflector and the center of the cavity.

### CROSS-REFERENCE TO RELATED APPLICATIONS

This application claims priority to International Application Number PCT/CN2024/071294, filed on Jan. 9, 2024, the contents of which are hereby incorporated by reference in their entirety.

### BACKGROUND

Conventional technologies for solid-state lighting (e.g., light emitting diodes (LEDs)) struggle to achieve color consistency. That is, color consistency is one of many challenges for conventional technologies for solid-state lighting. Additionally, conventional technologies for solid-state lighting struggle to improve color over angle (COA), which is a critical metric of color variation as a function of angle. For example, while conventional COA improvement approaches include adding surface roughness, spraying nanoparticles on top of an emitting surface, adding diffusers in an encapsulant silicone, and implementing phosphor sediment process, conventional COA improvement approaches reduce a luminous flux due to re-absorption and/or provide only limited improvement in COA.

By way of example, conventional technologies for solid-state lighting embody general characteristic of LEDs with lateral chip and dispensed phosphor (e.g., most mid-power and chip-on-board (COB) LEDs). The general characteristics include that light emitted at low angles is more down-converted than light emitted at high angles, which results in COA variations. The problem that the conventional technologies for solid-state lighting cannot solve is how to improve the COA without adversely affecting light extraction efficiency.

Thus, there is a need for a LED package with improved light quality.

### SUMMARY

According to one or more embodiments, a light emitting diode package is provided. The light emitting diode package includes molded lead frame package comprising a lead frame configured to define a cavity. The light emitting diode package includes a reflector configured on the molded lead frame package in a center of a cavity. The light emitting diode package includes one or more chips mounted on the molded lead frame package and configured in a symmetric shape around the reflector and the center of the cavity.

According to one or more embodiments, the light emitting diode package described herein can be embodied in a device, an apparatus, a method, and a system.

### BRIEF DESCRIPTION OF THE DRAWINGS

A more detailed understanding can be had from the following description, given by way of example in conjunction with the accompanying drawings wherein:

FIG. 1 depicts a diagram of method according to one or more embodiments;

FIG. 2 depicts a diagram of device according to one or more embodiments;

FIG. 3 depicts a diagram of device according to one or more embodiments;

FIG. 4 depicts a diagram of device according to one or more embodiments; and

FIG. 5 depicts a diagram of device according to one or more embodiments.

### DETAILED DESCRIPTION

According to one or more embodiments, described herein is a light emitting diode (LED) package with improved light quality. The LED package includes an arrangement of one or more positions of one or more chips within (e.g., a chipset rearrangement) the LED package. The arrangement can form a symmetric shape with a reflector at a center of the LED package. By way of example, the chipset rearrangement and the reflector of the LED package redirects light rays (e.g., blue rays) escaping from inner sides of the one or more chips to lower angles to improve a light quality (e.g., improve a COA). Further, the reflector reduces light propagating in a horizontal direction and brings better light extraction efficiency. According to one or more technical effects, benefits, and advantages, the LED package proves a symmetrically shaped chip arrangement and a center reflector to improve COA and light extraction efficiency (e.g., improved COA without adversely affecting, and in fact improving, light extraction efficiency). Thus, the LED package emphasizes color performance with color consistency over the space.

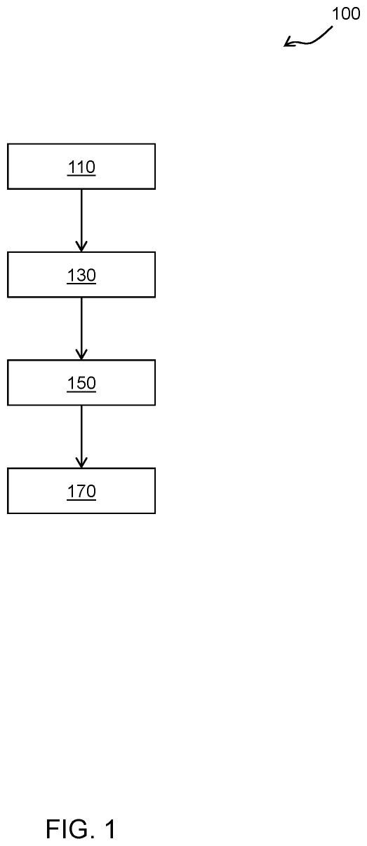

FIG. 1 depicts a diagram of method 100 according to one or more embodiments. The method 100 can be implemented by manufacturing equipment for constructing a LED package. The method begins at block 110, where a substrate receives a molded frame. The substrate is an initial substrate of the LED package, which will result from the completion of the method 100. The molded frame can include lead. According to one or more embodiments, the LED package comprises a molded lead frame on a substrate (e.g., a molded lead frame package).

At block 120, one or more chips are mounted on the molded lead frame package. For instance, a die bond process places dies (e.g., the one or more chips) to form a symmetric shape. The one or more chips can include two or more lateral chips and/or flip chips.

The one or more chips can include a COB module or any other package where one or more dies of the COB or other package are mounted inside a cavity of the molded lead frame package. The cavity of the molded lead frame package can be filled with a phosphor silicone matrix. The phosphor silicone matrix receives the one or more chips. According to one or more embodiments, the LED package with at least two (2) LED die (e.g., the one or more chips) and a dispensed phosphor. According to one or more embodiments, the one or more chips can include a quantity selected from two (2) to fifty (50). For example, the quantity of the one or more chips for the LED package can be two (2), four (4), six (6), eight (8), ten (10), twelve (12), etc.

According to one or more embodiments, the LED package with at least four (4) LED die. The at least four (4) LED die (e.g., the one or more chips) can have a rectangular aspect ratio. The at least four (4) LED die can be laid in a substantially symmetric arrangement (e.g., the symmetric shape), for example, a long side of each die is facing a center of the LED package.

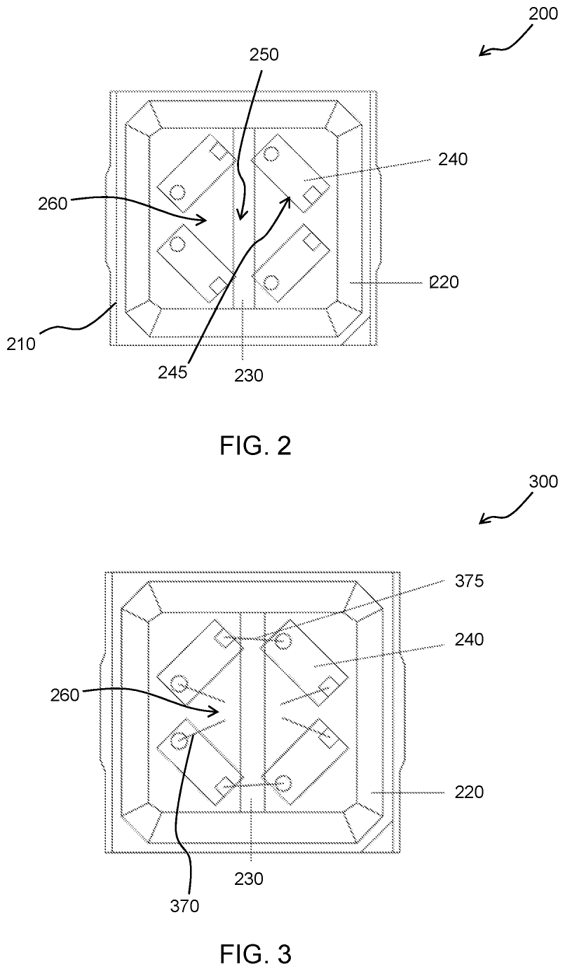

Turning to FIG. 2, a diagram of device 200 is depicted according to one or more embodiments. The device 200 includes a molded lead frame package 210, with a lead frame 220 and an isolation rod 230. As shown in FIG. 2, four (4) LED die 240 are arranged in a symmetric shape. The symmetric shape can include a rectangular aspect ratio. The symmetric shape can include a substantially symmetric arrangement of the four (4) LED die 240, where a long side 245 of each die 240 is facing a center 250 of the package. Note that a cavity of the molded lead frame package 210 is within the lead frame 220 and is filled with a phosphor silicone matrix 260.

Returning to FIG. 1, at block 130, a wire bond process is performed. The wire bond process connects the one or more chips to the molded lead frame package. Turning to FIG. 3, a diagram of device 300 is depicted according to one or more embodiments. The device 300 shows a result of the wire bond process. Accordingly, central bond wires 370 connect each die 240 to landing spots within the phosphor silicone matrix 260, while at least one wire 375 connects two dies 240 (e.g., over the isolation bar 230).

Returning to FIG. 1, at block 140, a reflector is provided. For instance, the reflector can be created for, deposited on, or integrated in the LED package. The reflector can be dispensed and cured in the LED package. The reflector can be fabricated separately from the LED package and glued therein. The reflector can be integrated as part of the molded lead frame package.

The reflector can be made of any reflective material (e.g., titanium dioxide). The reflector can include silicone loaded with TiO2 particles.

A shape of the reflector can have a height. The height can be selected from range of 50 micro-meters (μm) to 500 μm. By way of example, the height of the reflector can be 100 μm, 150 μm, 200 μm, or 250 μm. The height controls a COA, for example, a COA curve for a 200 μm height is ideally close to a horizontal axis.

The shape of the reflector can have one or more sloped sides. The one or more sloped sides redirect (e.g., upwards or in a direction normal to a plane of the LED package) light emitted from sides of the one or more chips (e.g., long side 245 of each die 240).

The reflector can be provided in a space. The space can be oriented in a center of the LED package. The space can be between two of more die (e.g., centrally oriented between the four (4) LED die).

According to one or more embodiments, the reflector can be created or deposited by dispensing and curing of a volume of titanium dioxide (TiO2) loaded silicone. The shape of the reflector can be defined by the dispensing process.

According to one or more embodiments, for higher die quantities, the LED package can include at least two arrangements of the one or more chips in multiple symmetric cells. Further, the reflector can be at a center of each of the multiple symmetric cells. Thus, the LED package can include a plurality of reflectors.

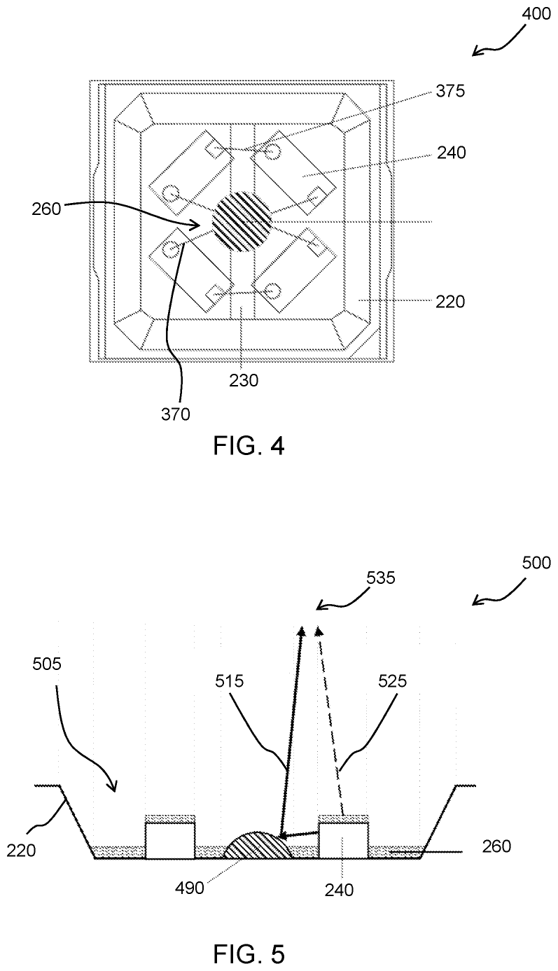

Turning to FIG. 4, a diagram of device 400 is depicted according to one or more embodiments. The device 400 includes a reflector 480. The reflector 480 can be in a center of the package (e.g., the center 250 of the package as shown in FIG. 2). As shown in FIG. 4, the reflector 480 can be positioned to cover landing spots of the central bond wires 370 to reduce absorption losses.

FIG. 5 depicts a diagram of device 500 according to one or more embodiments. The device 500 can be a sedimented phosphor package. Thus, FIG. 5 generally shows an illustration of color remixing mechanism in the sedimented phosphor package. The device 500 shows a cavity 505, a blueish ray 515, a yellowish ray 525, and a color remix in a space 535, along with the lead frame 220, the die 240, the phosphor silicone matrix 260, and the reflector 490. As shown in FIG. 5, the blueish ray 515 exits a side of the die 240 and is redirected upwards (e.g., in a direction normal to a plane of the phosphor silicone matrix 260).

According to one or more embodiments, the LED package as described here provides the technical effects, benefits, and advantages of improved COA, color consistency, and light quality improvement for indoor and/or outdoor applications.

Examples of different light illumination systems and/or light emitting diode (“LED”) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

As would be apparent to one skilled in the relevant art, based on the description herein, embodiments of the present invention can be designed in software using a hardware description language (HDL) such as, for example, Verilog or VHDL. The HDL-design can model the behavior of an electronic system, where the design can be synthesized and ultimately fabricated into a hardware device. In addition, the HDL-design can be stored in a computer product and loaded into a computer system prior to hardware manufacture.

Having described the embodiments in detail, those skilled in the art will appreciate that, given the present description, modifications may be made to the embodiments described herein without departing from the spirit of the inv concept. Therefore, it is not intended that the scope of the invention be limited to the specific embodiments illustrated and described.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

What is claimed is:

1. A light emitting diode package comprising:
molded lead frame package comprising a lead frame configured to define a cavity;
a reflector configured on the molded lead frame package in a center of a cavity; and
one or more chips mounted on the molded lead frame package and configured in a symmetric shape around the reflector and the center of the cavity.

2. The light emitting diode package of claim 1, wherein the reflector comprises a height selected from range of 50 micro-meters (μm) to 500 μm.

3. The light emitting diode package of claim 1, wherein the one or more chips can include two or more lateral chips or flip chips.

4. The light emitting diode package of claim 1, wherein the cavity of the molded lead frame package is filled with a phosphor silicone matrix.

5. The light emitting diode package of claim 1, wherein the one or more chips can include at least four (4) light emitting diode dies.

6. The light emitting diode package of claim 1, wherein a long side of each chip of the one or more chips faces the reflector and the center of the cavity.

7. The light emitting diode package of claim 1, wherein the symmetric shape comprises a rectangular aspect ratio.

8. The light emitting diode package of claim 1, wherein the light emitting diode package comprises one or more central bond wires that connect each chip of the one or more chips to landing spots within a phosphor silicone matrix.

9. The light emitting diode package of claim 1, wherein the reflector is formed by dispensing and curing a material in the light emitting diode package.

10. The light emitting diode package of claim 1, wherein the reflector is fabricating separately from the light emitting diode package and glued into the center of the cavity.

11. The light emitting diode package of claim 1, wherein the reflector is integrated into the molded lead frame package.

12. The light emitting diode package of claim 1, wherein the reflector comprises titanium dioxide.

13. The light emitting diode package of claim 1, wherein a shape of the reflector comprises one or more sloped sides.

14. The light emitting diode package of claim 1, wherein a shape of the reflector is defined by a dispensing process.

15. The light emitting diode package of claim 1, wherein the light emitting diode package comprises at least two arrangements of the one or more chips in multiple symmetric cells and at least two reflectors configured at a center of each of the multiple symmetric cells.

16. The light emitting diode package of claim 1, wherein the reflector is configured to cover one or more landing spots of one or more central bond wires of the one or more chips to reduce absorption losses.

17. The light emitting diode package of claim 1, wherein the reflector is configured to divert a first light ray received from a side of the one or more chips upwards to enable a color remixing with a second light ray.

18. The light emitting diode package of claim 1, wherein the reflector comprises a height of 200 micro-meters (μm).

19. The light emitting diode package of claim 1, wherein the reflector comprises a titanium dioxide (TiO2) loaded silicone.

20. The light emitting diode package of claim 1, wherein a shape of the reflector is a result of dispensing and curing of a volume of titanium dioxide (TiO2) loaded silicone in the center of the cavity.
